(19) United States
(12) Patent Application Publication
(10) Pub. No.: US 2012/0292088 A1
(43) Pub. Date: Nov. 22, 2012

(54) ELECTRONIC DEVICE WITH OBLIQUELY CONNECTED COMPONENTS

(75) Inventor: Chuan-Hsin Lee, Taipei (TW)

(73) Assignee: INVENTEC CORPORATION, Taipei (TW)

(21) Appl. No.: 13/217,479

(22) Filed: Aug. 25, 2011

(30) Foreign Application Priority Data
May 20, 2011 (TW) 100117850

(51) Int. Cl. H05K 1/16; B23K 1/20; B23K 31/02

(52) U.S. Cl. 174/260; 228/179.1

(57) ABSTRACT

According to the disclosure, an electronic device comprising a circuit board and an electrical component is disclosed. The circuit board has a first surface and includes a solder pad array including solder pads. The solder pad array is disposed on a first surface of the circuit board, and the circuit board further has vias passing through the solder pads and the circuit board. The electrical component is disposed on the first surface and between two of the solder pads next to each other. The electrical component includes two contacts electrically connected to the two solder pads next to each other. A line passing through the centers of the two contacts forms an acute angle with a line passing through the centers of the two solder pads next to each other.

### CROSS-REFERENCE TO RELATED APPLICATIONS

This non-provisional application claims priority under 35 U.S.C. §119(a) on Patent Application No(s). 100117850 filed in Taiwan, R.O.C. on May 20, 2011, the entire contents of which are hereby incorporated by reference.

### BACKGROUND

1. Technical Field

The disclosure relates to electronic devices, and more particularly to electronic devices with circuit boards on which electrical components are attached.

2. Related Art

A capacitor is usually connected with a printed circuit board by fixing contacts of the capacitor to solder pads of the circuit board by solder reflowing. However, for printed circuit boards with vias passing through the solder pads, during the reflow soldering, part of the liquefied solder wicks down into the vias, frequently causing insufficient solder to remain on the solder pads. An insufficient solder condition causes loose connections between the contacts and the solder pads.

To prevent such problems, vias of some printed circuits board are filled with metal by plating in order to prevent liquefied solder from flowing into the vias during reflow soldering. Therefore, solder preserved on the solder pads is sufficient to make good electrical connections between the solder pads and the contacts.

Although capable of preventing such problems, filling the vias with metal is expensive. Also, filling vias with metal can cause unwanted changes in the dimensions of the solder pads. When the sizes of the solder pads, connected to the contacts of the capacitor, are not identical, the capacitor on the solder pads may slide relative to the circuit board during reflow soldering, and, therefore, after the liquefied solder is hardened, the capacitor deviates from the position where the capacitor is supposed to be.

### SUMMARY

According to one embodiment, an electronic device comprising a circuit board and an electrical component is disclosed. The circuit board has a first surface and includes a solder pad array including solder pads. The solder pad array is disposed on a first surface of the circuit board, and the circuit board further has vias passing through the solder pads. The electrical component is disposed on the first surface and between two of the solder pads next to each other. The electrical component comprises two contacts electrically connected to the two solder pads next to each other. A line passing through the centers of the two contacts forms an acute angle with a line passing through the centers of the two solder pads next to each other.

According to another embodiment, a method is provided of electrically connecting an electrical component having two contacts to two corresponding solder pads of a circuit board, wherein vias pass through the solder pads. The method uses reflow soldering to permanently connect the electrical component to the solder pads. Solder paste is applied to each solder pad (which is preferably circular) along only a narrow (i.e., less than 180° and preferably less than 90°) outer arc segment of the solder pad. Solder paste is not applied to the via passing through the center of the solder pad. The center of each contact of the electrical component is positioned at least one solder pad radius away from the center of its corresponding solder pad. With the electrical component so oriented, a first line passing through centers of the two contacts forms an oblique angle of between 45 and 90 degrees, and more preferably, between 65 and 70 degrees, with a second line passing through centers of the two solder pads. Moreover, a first of the two contacts intersects an outer edge of the corresponding solder pad on substantially only one side of the second line, and a second of said two contacts intersects an outer edge of its corresponding solder pad on substantially only an opposite side of the second line. Reflow soldering is then applied to the contacts of the electrical component to the solder pads. This method of connecting electrical components is systematically, consistently, and automatically applied to each of a plurality of electrical components to a circuit board.

### BRIEF DESCRIPTION OF THE DRAWINGS

Unless otherwise specified, the same reference numbers are used throughout the drawings to refer to the same or like elements of embodiments, and wherein:

FIG. 1A is a bottom view of an electronic device according to an embodiment;

FIG. 1B is an enlarged plan view of a partial structure in FIG. 1A;

FIG. 2 is a sectional view of the electronic device taken along line 2-2 in FIG. 1A; and

FIG. 3 is a plan view of a partial structure of another embodiment of an electronic device.

### DETAILED DESCRIPTION

In the following description, for the purpose of explanation, numerous specific details are set forth in order to provide a thorough understanding of the detailed embodiments. It will be apparent, however, that one or more embodiments may be practiced without these specific details. In other instances, well-known structures and elements are schematically shown in order to simplify the drawings.

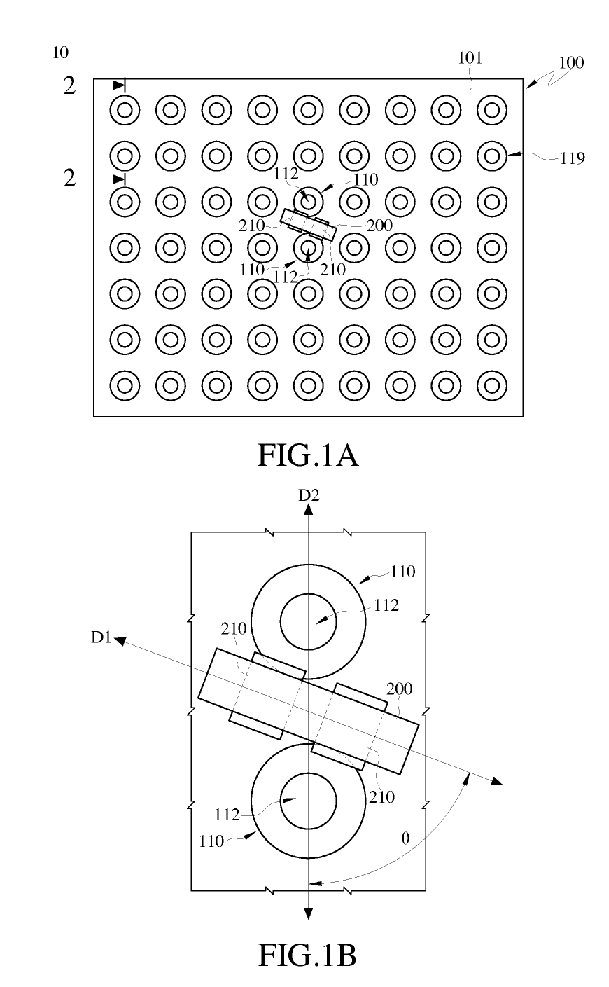

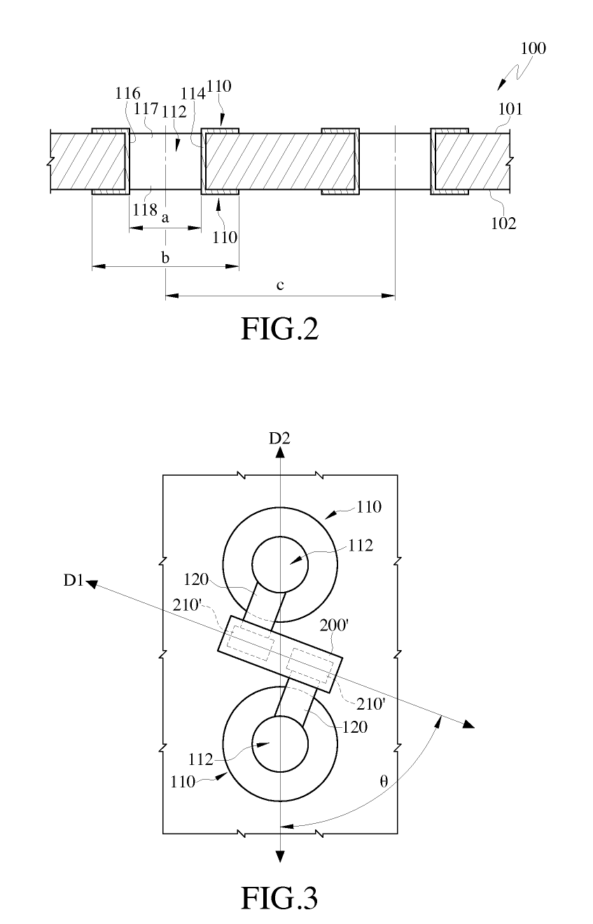

Refer to FIGS. 1A, 1B and 2, where FIG. 1 is a bottom view of an electronic device 10 according to an embodiment; FIG. 1B is an enlarged plan view of a partial structure in FIG. 1A; and FIG. 2 is a sectional view of the electronic device taken along line 2-2 in FIG. 1A. The electronic device 10 comprises a circuit board 100, such as a printed circuit board, and an electronic element or electrical component 200, such as a capacitor.

In this embodiment, the circuit board 100 is a double-side-printed circuit board which has a first surface 101 and a second surface 102 opposite to the first surface 101. The circuit board further comprises two solder pad arrays 119 respectively disposed on the first surface 101 and the second surface 102. Each solder pad array 119 comprises solder pads 110. The solder pads 110, which are circular, are formed on the first surface 101 and the second surface 102 through, for example, screen printing or plating.

Each solder pad 110 on the first surface 101 is coaxially aligned with a solder pad 110 on the second surface 102. The circuit board 100 has vias 112 passing through the circuit board 100 so that an entry 117 of each via 112 is on the first surface 101 and the other entry 118 of each vias 112 is on the second surface 102.

As shown in FIG. 2, the entry 117 of the via 112 is surrounded by the solder pad 110 on the first surface 101 and the entry 118 of the same via 112 is surrounded by the solder pad 110 which is on the second surface 102 and coaxially aligned with such solder pad 110 on the first surface. In this and some embodiments, the entry 117 and the entry 118 are in the centers of the corresponding solder pads 110 surrounding the entry 117 and the entry 118. That is, the longitudinal axis of the via 112 passes through the centers of the corresponding pair of the solder pads 110 disposed on the first surface 101 and the second surface 102.

By, for example, plating, a conductive layer 114, as shown in FIG. 2, is formed on an inner wall 116, which forms the via 112, of the circuit board 100. The conductive layers 114 electrically connect the solder pad 110 on the first surface 101 with the solder pad 110 on the second surface 102, so that signals may be transferred between the solder pad 110 on the first surface 101 and the solder pad 110 on the second surface 102.

The dimensions of the circuit board 100 are illustrated as the following. In FIG. 2, the outer diameter b of the solder pad 110 is approximately 18 mil; the diameter a of the via 112 is approximately 9 mil; and the distance c between the longitudinal axes of the two adjacent vias 112 is approximately 0.8 millimeter (mm).

In FIGS. 1A and 1B, the electrical component 200 is disposed on the first surface 101 of the circuit board 100. This embodiment, however, does not intend to limit the position of the electrical component 200. In some embodiment, the electrical component 200 is disposed on the second surface 102.

The electrical component 200, such as a capacitor, comprises two contacts 210. The electrical component 200 is located between two adjacent solder pads 110; the two adjacent solder pads 110 are electrically connected to the pair of the contacts 210 with solder. A line D1 passing through the centers of the pair of the contacts 210 forms an oblique angle θ with a line D2 passing through the centers of the pair of the solder pads 110.

If the distance from the contact 210 to the center of the solder pad 110 closest to such contact 210 is not long enough, during reflow soldering, the liquefied solder is likely to wick into the vias. Therefore, the amount of solder remaining on the solder pad 110 may be insufficient to securely electrically connect such contact 210 to the solder pad 110.

To solve this problem, and as illustrated in FIG. 1B, the center of each contact 210 is positioned at least one solder pad radius away from the center of the solder pad 110 to which the contact 210 is to be connected. This displacement is provided to prevent solder from wicking into the via 112 of the corresponding solder pad 110. Also, the electrical component 200 is angularly oriented with respect to the solder pads 110 to which it will be connected so that each of its contacts 210 intersects an outer edge of its corresponding solder pad 110 on opposite sides, and on substantially only those opposite sides, of the line D2. Moreover, solder paste for connecting each contact 210 to its corresponding solder pad 110 is limited to substantially only a narrow outer arc segment of the solder pad 110, under and immediately adjacent to the area where the contact 210 intersects with its corresponding solder pad 110, without placing any of the solder paste on the via 112 passing through the solder pad 110. The circuit board 100 is then subjected to controlled heat to melt the solder and connect the contacts 210 to the solder pads 110. This positioning and solder application technique is systematically and consistently applied, in an automated fashion, to each of a plurality of electrical components 200 soldered to the circuit board 100.

With the electrical component 200 so oriented, and its contacts so displaced from the centers of their corresponding solder pads, the angle θ between lines D1 and D2 is acute, and typically between 45 and 90 degrees. In some embodiments, the angle θ is in a range from 65 degrees to 70 degrees. In some embodiments, the acute angle θ equals 67.5 degrees, so that the distance from the contact 210 to the solder pad 110 closest to the contact 210 is longest.

In FIG. 1B, the contacts 210 are in contact with the solder pads 110. However, in some embodiments, the contacts 210 may be connected to the corresponding pads 110 indirectly. FIG. 3 is a plane view a partial structure of another embodiment of an electronic device. The circuit board 100 comprises conductive traces 120 on the first surface 101. The contacts 210′ of the electrical component 200′ are electrically connected to the pair of the adjacent solder pads 110 by the traces 120.

Since the line passing through the pair of the adjacent contacts forms the acute angle θ, which may be close to 67.5 degrees, relative to the line passing through the centers of the pair of adjacent solder pads, the distance from the contact to solder pad closest to such contact is appropriate. This distance would be long enough to prevent the liquefied solder originally disposed on the solder pad from flowing into the via during reflow soldering, and, therefore, the problem of bad or no electrical connection between the contact and the solder pad due to insufficient solder is avoided.

What is claimed is:

1. An electronic device comprising:
a circuit board having a first surface and including a solder pad array including solder pads, the solder pad array being disposed on a first surface of the circuit board, and the circuit board further having vias passing through the solder pads; and
an electrical component disposed on the first surface and between two adjacent solder pads, the electrical component including two contacts electrically connected to the two adjacent solder pads, wherein a line passing through the centers of the two contacts form an acute angle with a line passing through the centers of the two solder pads next to each other.

2. The electronic device according to claim 1, wherein the acute angle is in a range from 65 degrees to 70 degrees.

3. The electronic device according to claim 1, wherein the acute angle is 67.5 degrees.

4. The electronic device according to claim 1, further comprising two conductive traces disposed on the first surface, each conductive trace extending radially outward from one of the adjacent solder pads, and each conductive trace electrically connecting a contact of the electrical component with a corresponding solder pad.

5. The electronic device according to claim 1, wherein:
the circuit board further has a second surface opposite to the first surface and comprises another solder pad array disposed on the second surface,
the another solder pad array comprises solder pads,
each of the solder pads on the first surface is coaxially aligned with one of the solder pads on the second surface, and
the circuit board further comprises conductive layers disposed on inner walls, which form the vias, of the circuit board, which electrically connect the solder pads on the first surface with the solder pads on the second surface.

6. The electronic device according to claim 1, wherein the solder pads on the first surface and the second surface are circular, and the outer diameter of the solder pads on the first surface and the second surface are approximately 18 mil.

7. The electronic device according to claim 1, wherein the diameters of the vias are approximately 9 mil.

8. The electronic device according to claim 1, wherein the distance between the longitudinal axes of the two vias next to each other is approximately 0.8 millimeter.

9. The electronic device according to claim 1, wherein the electrical component is a capacitor.

10. The electronic device according to claim 1, wherein the solder pads on the first surface and the second surface are circular, the outer diameter of the on the first surface and the second surface are approximately 18 mil, the diameters of the vias are approximately 9 mil, and the distance between the longitudinal axes of the two vias next to each other is approximately 0.8 millimeter.

11. A method of electrically connecting an electrical component having two contacts to two solder pads of a circuit board, wherein vias pass through the solder pads, the method comprising:
positioning the contacts of the electrical component on the circuit board so that a first line passing through centers of the two contacts forms an oblique angle with a second line passing through centers of the two solder pads, such that a first of said two contacts intersects an outer edge of a first of said two solder pads on substantially only one side of the second line, and a second of said two contacts intersects an outer edge of a second of said two solder pads on substantially only an opposite side of the second line; and
reflow soldering the contacts of the electrical component to the solder pads.

12. The method of claim 11, wherein each solder pad has a radius, and the center of each contact is positioned at least one solder pad radius away from the center of the solder pad to which the contact is connected.

13. The method of claim 12, wherein the oblique angle is between 45 and 90 degrees.

14. The method of claim 13, further comprising applying solder paste for connecting each contact to substantially only a narrow outer arc segment of the corresponding solder pad, without placing solder paste on the via passing through the solder pad.

15. The method of claim 14, further comprising subjecting the circuit board to controlled heat to melt the solder and connect the contacts to the solder pads.

16. A method of systematically electrically connecting a plurality of electrical components, each having two contacts, to corresponding solder pads of a circuit board, wherein vias pass through the solder pads, the method comprising:
systematically and automatically positioning each of the electrical components on the circuit board so that a first line passing through centers of the two contacts forms an oblique angle with a second line passing through centers of the two corresponding solder pads, such that a first of said two contacts intersects an outer edge of a first of said two solder pads on substantially only one side of the second line, and a second of said two contacts intersects an outer edge of a second of said two solder pads on substantially only an opposite side of the second line; and
reflow soldering the contacts of the electrical components to the solder pads.

17. The method of claim 16, wherein each solder pad has a radius, and the center of each contact is positioned at least one solder pad radius away from the center of the solder pad to which the contact is connected.

18. The method of claim 17, wherein the oblique angle is between 45 and 90 degrees.

19. The method of claim 18, further comprising applying solder paste for connecting each contact to substantially only a narrow outer arc segment of each solder pad, without placing solder paste on the via passing through the solder pad.

20. The method of claim 19, further comprising subjecting the circuit board to controlled heat to melt the solder and connect the contacts to the solder pads.
